(19) United States
(12) Patent Application Publication
(10) Pub. No.: US 2025/0251423 A1
(43) Pub. Date: Aug. 7, 2025

(54) POGO PIN PROBE AND POGO PIN INCLUDING SAME

(71) Applicant: SAE HAN MICRO TECH CO., LTD., Namyangju-si (KR)

(72) Inventor: Jea Hyoung LEE, Hwaseong-si (KR)

(21) Appl. No.: 19/186,638

(22) Filed: Apr. 23, 2025

Related U.S. Application Data
(63) Continuation of application No. PCT/KR2023/009831, filed on Jul. 11, 2023.

(30) Foreign Application Priority Data
Oct. 26, 2022 (KR) 10-2022-0139132

(51) Int. Cl. G01R 1/067

(52) U.S. Cl. CPC G01R 1/06722

(57) ABSTRACT

Provided are a pogo pin probe that can be fixed to a barrel of a pogo pin without rattling/rotating; and a pogo pin including same. The pogo pin probe, partially inserted into the barrel of the pogo pin, comprises: at least one contact portion having a sharp end in contact with an object to be inspected; a first body portion disposed outside the barrel and having one end coupled to the other end of the contact portion; a second body portion disposed inside the barrel and having one end coupled to the other end of the first body portion; a third body portion having a toothed wheel shape, disposed inside the barrel, and having one end coupled to the other end of the second body portion; and a fourth body portion disposed inside the barrel and having one end coupled to the other end of the third body portion.

### TECHNICAL FIELD

The present disclosure relates to a pogo pin probe and a pogo pin including the same and, more particularly, to a pogo pin probe that can be accurately fixed to a barrel of a pogo pin without rattling or rotating, and a pogo pin including the probe.

### BACKGROUND ART

A test socket is used to electrically connect a test subject and test equipment to check the performance of the test subject, such as a semiconductor device or display device, during or after the production of the test subject.

The test socket has a plurality of pogo pins for electrically connecting the terminal of the test subject and the pads of the test equipment.

Korean Patent No. 10-2216143 and Korean Patent Application Publication No. 10-2019-0010674 disclose pogo pins having a probe member, a conductive cylindrical plunger, and a pipe surrounding the probe member and the plunger. An elastic member is arranged inside the pipe to provide elastic force to bias the probe member and the plunger toward the outside of the pipe.

In the case of such conventional pogo pins, in order to secure the probe member to the pipe, a part of the probe member is inserted into the pipe and then the pipe is recessed so that the probe member is caught in the recessed portion of the pipe.

However, the probe member fixed in this way may rotate or shake with respect to the pipe. If the probe member rotates during the measurement process, accurate measurement may be difficult, and if rotation or rattling is repeated, the probe member may become separated from the pipe.

### Document of Related Art

Korean Patent No. 10-2216143

Korean Patent Application Publication No. 10-2019-0010674

### DISCLOSURE

### Technical Problem

The present disclosure is intended to solve the above problems occurring in the related art. An objective of the present disclosure is to provide a pogo pin probe that can be securely fixed to a barrel of a pogo pin without rattling or rotating, and a pogo pin including the probe.

### Technical Solution

In order to achieve the above mentioned objectives, there is provided a pogo pin probe that is partially inserted into a barrel of a pogo pin, the probe including: at least one contact portion having a pointed end that contacts a test subject; a first body portion disposed outside the barrel, and having a first end coupled to a second end of the contact portion; a second body portion disposed inside the barrel, and having a first end coupled to a second end of the first body portion; a third body portion disposed inside the barrel, having a first end coupled to a second end of the second body portion, and having a toothed wheel shape; and a fourth body portion disposed inside the barrel, having a first end coupled to a second end of the third body portion.

In addition, teeth of the third body portion may engage with a recessed portion of the barrel.

In addition, at least one through hole may be formed penetrating at least one of the second body portion, the third body portion, and the fourth body portion, and the first body portion may not have a through hole formed.

In addition, the through hole may be filled with a different material having a higher hardness than a surrounding material.

In addition, the second body portion may have a toothed wheel shape.

In addition, the fourth body portion may have a toothed wheel shape.

In addition, the maximum outer diameter of the third body portion may be smaller than an outer diameter of the second body portion and an outer diameter of the fourth body portion.

In addition, the present disclosure provides a pogo pin including: a barrel; a probe, a portion of which is inserted into the barrel; a plunger, a portion of which is inserted into the barrel; and an elastic member disposed inside the barrel and applying elastic force to the probe and the plunger in a direction in which the probe and the plunger move away from each other, wherein the probe is the above-described pogo pin probe.

### Advantageous Effects

A pogo pin probe according to the present disclosure has a third body portion in the shape of a toothed wheel, so that a recessed portion of a barrel of a pogo pin and the teeth of the third body portion mesh with each other. Therefore, there is an advantage in that the pogo pin probe does not rotate with respect to the barrel.

### DESCRIPTION OF DRAWINGS

FIG. 1 is a perspective view of a pogo pin according to an embodiment of the present disclosure.

FIG. 2 is an exploded perspective view of the pogo pin illustrated in FIG. 1.

FIG. 3 is an exploded perspective view of a pogo pin probe illustrated in FIG. 1.

FIG. 4 is a partial cross-sectional view of the pogo pin probe illustrated in FIG. 1.

FIG. 5 is a perspective view of a pogo pin probe according to another embodiment of the present disclosure.

FIG. 6 is a partial cross-sectional view of the pogo pin probe illustrated in FIG. 5.

FIG. 7 is a partial cross-sectional view of a pogo pin probe according to still another embodiment of the present disclosure.

### MODE FOR INVENTION

Hereinafter, embodiments of the present disclosure will be described in detail with reference to the attached drawings. However, the embodiments of the present disclosure may be modified into various other forms, and the scope of the present disclosure should not be construed as being limited to the embodiments described below. The embodiments of the present disclosure are provided to more completely explain the present disclosure to those with average knowledge in the art. Accordingly, the shapes of elements in the drawings are exaggerated for clearer explanation, and elements indicated by the same symbols in the drawings represent the same elements.

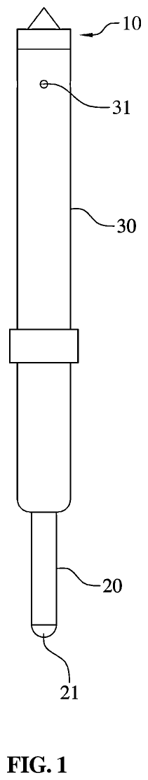

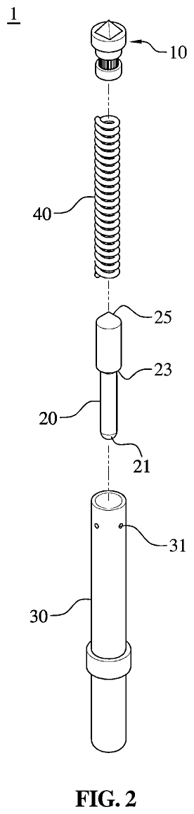

FIG. 1 is a perspective view of a pogo pin according to an embodiment of the present disclosure, and FIG. 2 is an exploded perspective view of the pogo pin illustrated in FIG. 1.

As shown in FIGS. 1 and 2, a pogo pin 1 according to an embodiment of the present disclosure includes a pogo pin probe 10, a plunger 20, a barrel 30, and an elastic member 40.

The pogo pin 1 electrically connects the terminal of a test subject and the pad of test equipment. The pogo pin probe 10 on one side of the pogo pin 1 is electrically connected to the terminal of the test subject, such as a semiconductor device or a display device, and a tip 21 of the plunger 20 exposed to the outside of the barrel 30 on the other side of the pogo pin 1 is electrically connected to the pad of the test equipment to test the electrical characteristics of the test subject.

The plunger 20 is generally a cylindrical conductor. A portion of the plunger 20 is inserted into the interior of the barrel 30. A step 23 is formed on the plunger 20 to prevent the plunger 20 from falling out of the barrel 30. An end portion 25 of the plunger 20 on the pogo pin probe 10 side has a cone shape with a diameter that becomes smaller as going toward the end. This is to allow the end of a coil spring, which is the elastic member 40, to be fitted. The plunger 20 may be made of tungsten, carbon steel, Cu alloy, Pd alloy, Au alloy, etc. The exposed tip 21 of the plunger 20 may have various shapes. In FIGS. 1 and 2, the tip 21 of the plunger 20 is depicted as being blunt, but the tip may also be in the shape of a cone or needle with a diameter that decreases toward the end, or may be flat.

The barrel 30 is a conductor that is generally cylindrical. The barrel 30 is also called a pipe or housing. In order for the plunger 20 to move freely in a straight line inside the barrel 30, the inner diameter of the barrel 30 is preferably somewhat larger than the outer diameter of the plunger 20. The barrel 30 may be made of nickel, a nickel alloy, gold-plated nickel, phosphor bronze, a copper alloy such as brass, etc. To prevent short-circuiting with an adjacent pogo pin 1, an insulating film may be coated on the outer surface of the barrel 30.

The elastic member 40 is placed inside the barrel 30. The elastic member 40 may be a coil spring. The elastic member 40 is arranged between the pogo pin probe 10 and the plunger 20. The elastic member 40 applies an elastic force to the pogo pin probe 10 and the plunger 20 in a direction in which the pogo pin probe 10 and the plunger 20 move away from each other.

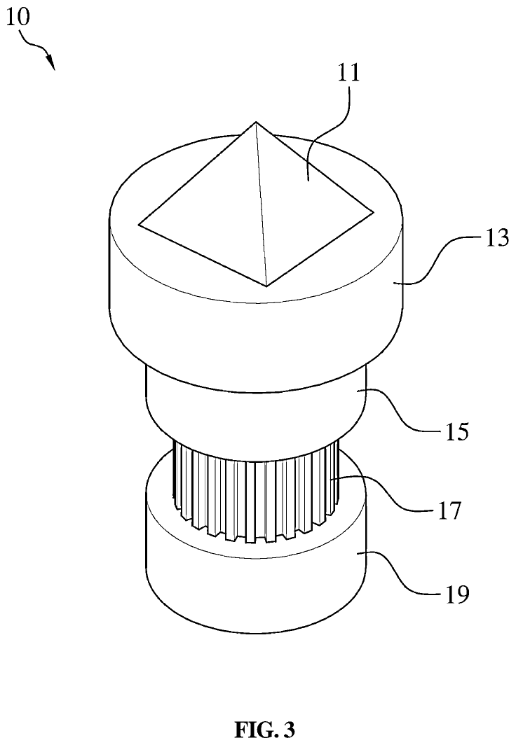

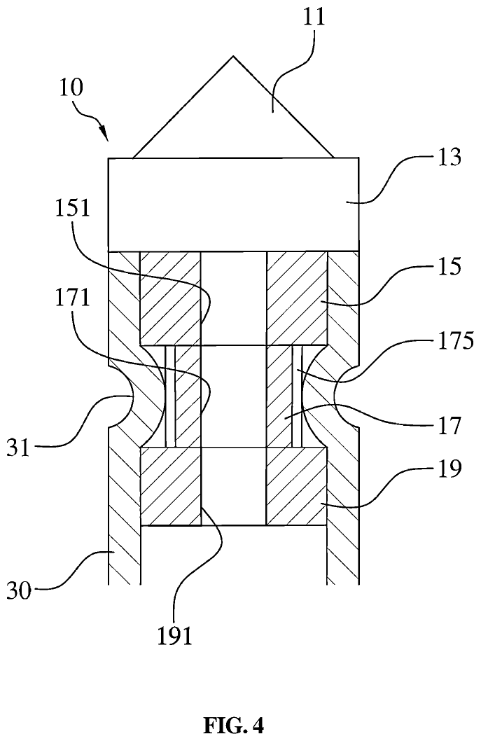

FIG. 3 is an exploded perspective view of a pogo pin probe illustrated in FIG. 1, and FIG. 4 is a partial cross-sectional view of the pogo pin probe illustrated in FIG. 1. The cross-sectional portion is hatch-patterned.

As shown in FIGS. 3 and 4, the pogo pin probe 10 includes a contact portion 11, a first body portion 13, a second body portion 15, a third body portion 17, and a fourth body portion 19 arranged in sequence along the length direction of the pogo pin 1. The pogo pin probe 10 may be manufactured through a micro-electromechanical systems (M EM S) process.

The contact portion 11 has a pointed end that comes into contact with a test subject such as a terminal of a semiconductor device. The pogo pin probe 10 includes at least one contact portion 11. The contact portion 11 has an area that increases from one end to the other. The contact portion 11 may have a square pyramid shape, as shown in FIGS. 3 and 4. In addition, the contact portion 11 may have a polygonal pyramid shape other than a cone or a square pyramid.

One end of the first body portion 13 is joined to the other end of the contact portion 11. The contact portion 11 is arranged at the center of the first body portion 13. As shown in FIGS. 3 and 4, the first body portion 13 may be generally in the shape of a cylinder. The first body portion 13 may also have the shape of a polygonal column. The diameter of the first body portion 13 is larger than the inner diameter of the barrel 30. Accordingly, the first body portion 13 is not inserted into the interior of the barrel 30, but is exposed to the outside of the barrel 30 together with the contact portion 11.

One end of the second body portion 15 is joined to the other end of the first body portion 13. The second body portion 15 may have a cylindrical or polygonal prism shape. The diameter of the second body portion 15 is smaller than or equal to the inner diameter of the barrel 30. Thus, the second body portion 15 is inserted into the interior of the barrel 30. It is preferable that a through hole 151 is formed in the center of the second body portion 15. Accordingly, the bending strength relative to the weight increases, the second body portion 15 may be prevented from bending due to the pressure applied when the pogo pin probe 10 comes into contact with the test subject.

One end of the third body portion 17 is joined to the other end of the second body portion 15. The third body portion 17 has a toothed wheel shape. The maximum outer diameter of the third body portion 17 is smaller than the inner diameter of the barrel 30. The maximum outer diameter is a diameter based on the tip of teeth 175. The maximum outer diameter of the third body portion 17 is smaller than the outer diameter of the second body portion 15. It is preferable that a through hole 171 is formed in the center of the third body portion 17.

One end of the fourth body portion 19 is joined to the other end of the third body portion 17. The fourth body portion 19 may be in the shape of a cylinder or polygonal column. The outer diameter of the fourth body portion 19 is smaller than or equal to the inner diameter of the barrel 30. The outer diameter of the fourth body portion 19 may be equal to the outer diameter of the second body portion 15. It is preferable that a through hole 191 is formed in the center of the fourth body portion 19.

The pogo pin probe 10 may be fixed to the barrel 30 by inserting the pogo pin probe 10 into the barrel 30 and then pressing the side of the barrel 30 to form at least one recessed portion 31. The recessed portion 31 protrudes toward the third body portion 17. The recessed portion 31 engages with the teeth 175 of the third body portion 17 to prevent the pogo pin probe 10 from rotating. In addition, the recessed portion 31 is caught between the other end of the second body portion 15 and one end of the fourth body portion 19 to prevent the pogo pin probe 10 from moving up and down.

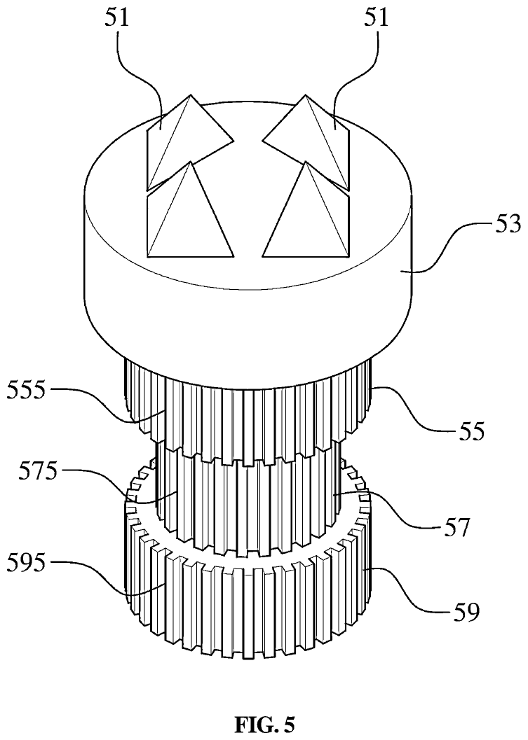

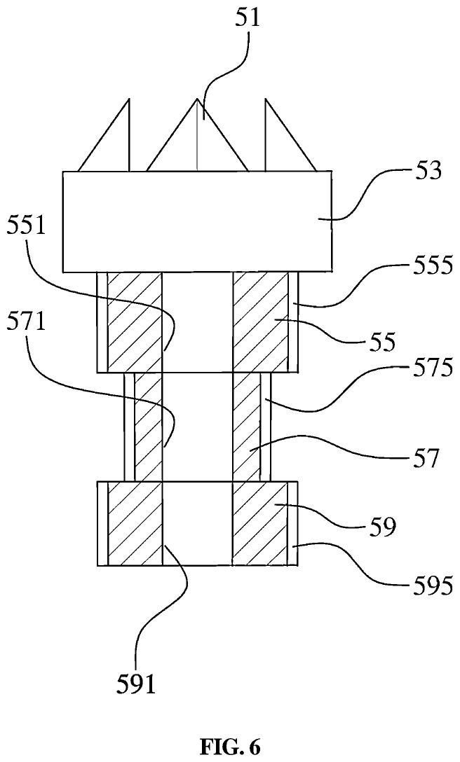

FIG. 5 is a perspective view of a pogo pin probe according to another embodiment of the present disclosure, and FIG. 6 is a partial cross-sectional view of the pogo pin probe illustrated in FIG. 5. The cross-sectional portion is hatch-patterned.

The pogo pin probe illustrated in FIGS. 5 and 6 differs from the pogo pin probe 10 illustrated in FIGS. 4 and 5 in that a second body portion 55 and a fourth body portion 59 also have a toothed wheel. The present embodiment is advantageous over the embodiment illustrated in FIGS. 4 and 5 in that the recessed portion 31 may engage with the teeth 555 and 595 of the second body portion 55 or the fourth body portion 59 when the recessed portion 31 is formed across the second body portion 55 or the fourth body portion 59.

In addition, the present embodiment differs from the pogo pin probe 10 illustrated in FIGS. 4 and 5 in that it has multiple contact portions 51. The present embodiment has four contact portions 51 in the shape of a triangular pyramid.

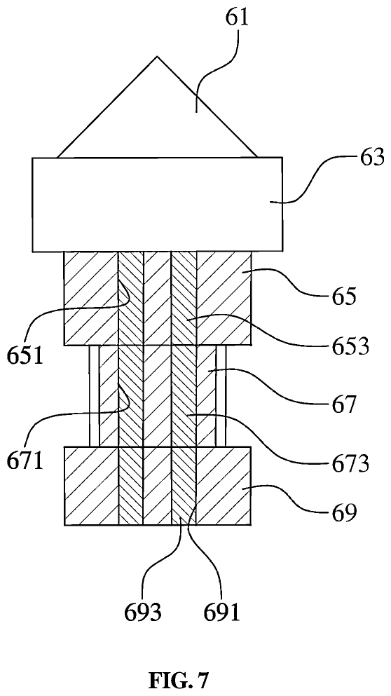

FIG. 7 is a partial cross-sectional view of a pogo pin probe according to still another embodiment of the present disclosure. The pogo pin probe illustrated in FIG. 7 includes second to fourth body portions 65, 67, and 69 including a plurality of through holes 651, 671, and 691. The present embodiment differs from the embodiment illustrated in FIGS. 3 and 4 in that the through holes 651, 671, and 691 are filled with different materials 653, 673, and 693 than that of the second to fourth body portions 65, 67, and 69.

The second to fourth body portions 65, 67, and 69 may be made of copper (Cu) or a copper alloy. These body portions 65, 67, and 69 have low hardness and may be bent or deformed by pressure.

As the different materials 653, 673, and 693, a resin or metal having higher hardness than the body portions 65, 67, and 69 may be used. As the metal, a metal including one or more elements selected from the group consisting of nickel (Ni), gold (Au), silver (Ag), carbon (C), palladium (Pd), rhodium (Rh), tin (Sn), ruthenium (Ru), and tungsten (W) may be used.

The pogo pin probe according to the present embodiment has the advantage of preventing bending or deformation by filling the through holes 651, 671, and 691 with the different materials 653, 673, and 693 having high hardness.

Although the preferred embodiments of the present disclosure have been illustrated and described above, the present disclosure is not limited to the specific embodiments described above, and can be implemented in various modifications by a person having ordinary knowledge in the technical field to which the present disclosure pertains without departing from the gist of the present disclosure claimed in the claims, and these modifications should not be understood as being separate from the technical idea or prospect of the present disclosure.

### DESCRIPTION OF REFERENCE NUMERALS

1: pogo pin
10: pogo pin probe
11, 51, 61: contact portion
13, 53, 63: first body portion
15, 55, 65: second body portion
17, 57, 67: third body portion
19, 59, 69: fourth body portion
20: plunger
30: barrel
40: elastic member

1. A pogo pin probe that is partially inserted into a barrel of a pogo pin, the probe comprising:
at least one contact portion having a pointed end that contacts a test subject;
a first body portion disposed outside the barrel, and having a first end coupled to a second end of the contact portion;
a second body portion disposed inside the barrel, and having a first end coupled to a second end of the first body portion;
a third body portion disposed inside the barrel, having a first end coupled to a second end of the second body portion, and having a toothed wheel shape; and
a fourth body portion disposed inside the barrel, having a first end coupled to a second end of the third body portion.

2. The pogo pin probe of claim 1, wherein teeth of the third body portion engage with a recessed portion of the barrel.

3. The pogo pin probe of claim 1, wherein at least one through hole is formed penetrating at least one of the second body portion, the third body portion, and the fourth body portion, and the first body portion does not have a through hole formed.

4. The pogo pin probe of claim 3, wherein the through hole is filled with a different material having a higher hardness than a surrounding material.

5. The pogo pin probe of claim 4, wherein the different material is a metal or resin containing one or more elements selected from the group consisting of nickel (Ni), gold (Au), silver (Ag), carbon (C), palladium (Pd), rhodium (Rh), tin (Sn), ruthenium (Ru), and tungsten (W).

6. The pogo pin probe of claim 1, wherein the second body portion has a toothed wheel shape.

7. The pogo pin probe of claim 1, wherein the fourth body portion has a toothed wheel shape.

8. The pogo pin probe of claim 1, wherein a maximum outer diameter of the third body portion is smaller than an outer diameter of the second body portion and an outer diameter of the fourth body portion.

9. A pogo pin comprising:
a barrel;
a probe, a portion of which is inserted into the barrel;
a plunger, a portion of which is inserted into the barrel; and
an elastic member disposed inside the barrel and applying elastic force to the probe and the plunger in a direction in which the probe and the plunger move away from each other,
wherein the probe is the pogo pin probe of claim 1.
